(19) United States
(12) Patent Application Publication
(10) Pub. No.: US 2019/0134677 A1
(43) Pub. Date: May 9, 2019

(54) LIQUID CIRCULATION SYSTEM

(71) Applicant: SHARP KABUSHIKI KAISHA, Sakai City (JP)

(72) Inventor: YUHSUKE TERAO, Sakai City (JP)

(21) Appl. No.: 16/179,838

(22) Filed: Nov. 2, 2018

(30) Foreign Application Priority Data
Nov. 6, 2017 (JP) 2017-213532

(51) Int. Cl. B08B 3/04; B01F 15/00

(52) U.S. Cl. CPC B08B 3/04; H01L 21/67075; B01F 15/00207

(57) ABSTRACT

A liquid circulation system includes a tank, a processing device, a first pump, a second pump, a liquid level sensor, and an adjuster. The tank is for storing a liquid. The processing device is for processing a subject using the liquid. The first pump is for feeding the liquid in the tank to the processing device. The second pump is for feeding the liquid used in the processing device to the tank. The liquid level sensor is for detecting a liquid level of the liquid in the tank below a threshold. The adjuster is for lifting the tank and adjusting a position of a surface of the liquid relative to the liquid level sensor to maintain the surface of the liquid above the liquid level sensor when an amount of the liquid in the tank is reduced.

### CROSS REFERENCE TO RELATED APPLICATION

This application claims priority from Japanese Patent Application No. 2017-213532 filed on Nov. 6, 2017. The entire contents of the priority application are incorporated herein by reference.

### TECHNICAL FIELD

The technology described herein relates to a liquid circulation system.

### BACKGROUND

A known system for wet processing includes a liquid circulation system for circulating a liquid between a tank and another section of the system for the processing. Examples of the system for wet processing include a cleaning system for cleaning substrates and a wet etching system. An example of such a system is disclosed in Japanese Patent Application Publication No. H11-176794. A system disclosed in the above patent application publication uses a pump for circulation of a cleaning liquid used in a cleaning tank.

If the circulation of the liquid is not properly performed due to a malfunction of the system and a liquid level in the tank is reduced, the pump may idle. When the pump is at idle, the pump is not cooled by the liquid. A temperature of the pump may increase and the pump may become overloaded. When the pump is at idle, dust may be produced by friction among components related to driving of the pump. To restrict the pump from idling, a liquid level sensor is installed to detect the liquid level in the tank. If the liquid level equal to or lower than a threshold (a lower limit), an alarm activates.

The liquid used in the liquid circulation system may have an expiration date for periodical replacement. For the replacement of the liquid, the liquid remaining in the tank and pipes need to be discarded and the tank is refilled with a new liquid. Then, the pump is turned on to feed the liquid to a processing device in the system (e.g., the cleaning tank). The liquid supplied from the tank to the processing device returns to the tank after a certain period of time. During the period of time, the liquid level in the tank is temporality lowered. The lowered liquid level may be detected by the liquid level sensor and the alarm may activate and the processing using the liquid circulation system may be stopped although this is not a malfunction of the system.

To solve such a problem, an amount corresponding to the lowered liquid level may be added to the amount of the liquid to refill the tank so that the liquid level in the tank remains above the threshold. However, this creates another problem, that is, an increase in the amount of the liquid used in the system.

### SUMMARY

The technology described herein was made in view of the above circumstances. An object is to replace a liquid without an extra amount of the liquid.

A liquid circulation system includes a tank, a processing device, a first pump, a second pump, a liquid level sensor, and an adjuster. The tank is for storing a liquid. The processing device is for processing a subject using the liquid. The first pump is for feeding the liquid in the tank to the processing device. The second pump is for feeding the liquid used in the processing device to the tank. The liquid level sensor is for detecting a liquid level of the liquid in the tank below a threshold. The adjuster is for lifting the tank and adjusting a position of a surface of the liquid relative to the liquid level sensor to maintain the surface of the liquid above the liquid level sensor when an amount of the liquid in the tank is reduced. The liquid fed from the tank to the processing device using the first pump is fed from the processing device to the tank using the second pump. According to the configuration, the processing using the liquid is performed by the processing device during the circulation of the liquid between the tank and the processing device. During replacement of the liquid in the tank with a new liquid, the new liquid is fed from the tank to the processing device using the first pump. Therefore, the amount of the liquid in the tank temporarily decreases. When the first pump is turned on and the amount of the liquid in the tank is reduced, the tank moves up. According to the configuration, the position of the surface of the liquid relative to the liquid level sensor is maintained above the liquid level sensor. Namely, an extra amount of the liquid is not required for restricting the activation of the liquid level sensor.

According to the technology described herein, an extra amount of the liquid is not required in replacement of the liquid.

### BRIEF DESCRIPTION OF THE DRAWINGS

FIG. 1 is a schematic view of a liquid circulation system according to a first embodiment.

FIG. 2 is a schematic view of the liquid circulation system including a tank without a chemical solution.

FIG. 3 is a schematic view of the liquid circulation system including the tank refilled with a chemical solution.

FIG. A is a schematic view of the liquid circulation system including a first pump in operation.

FIG. 5 is a schematic view of a liquid circulation system according to a comparative example.

FIG. 6 is a schematic view of the liquid circulation system according to the comparative example without a chemical solution.

FIG. 7 is a schematic view of the liquid circulation system according to the comparative example including a tank refilled with a chemical solution.

FIG. 8 is a schematic view of the liquid circulation system according to the comparative example including a first tank in operation.

FIG. 9 is a schematic view of a tank according to a second embodiment.

### DETAILED DESCRIPTION

### First Embodiment

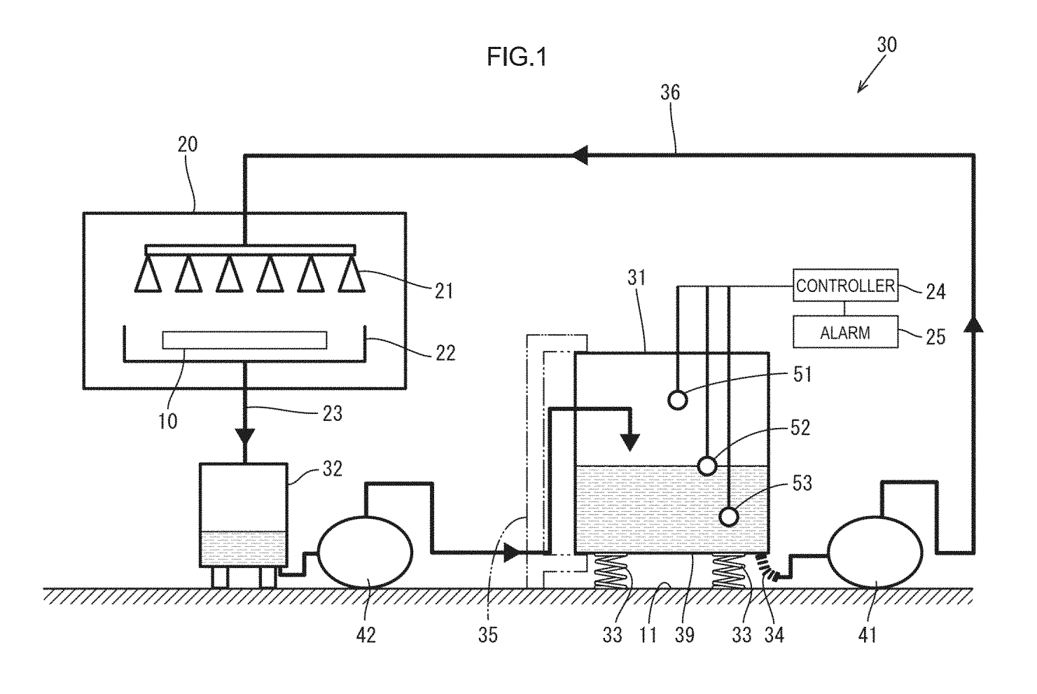

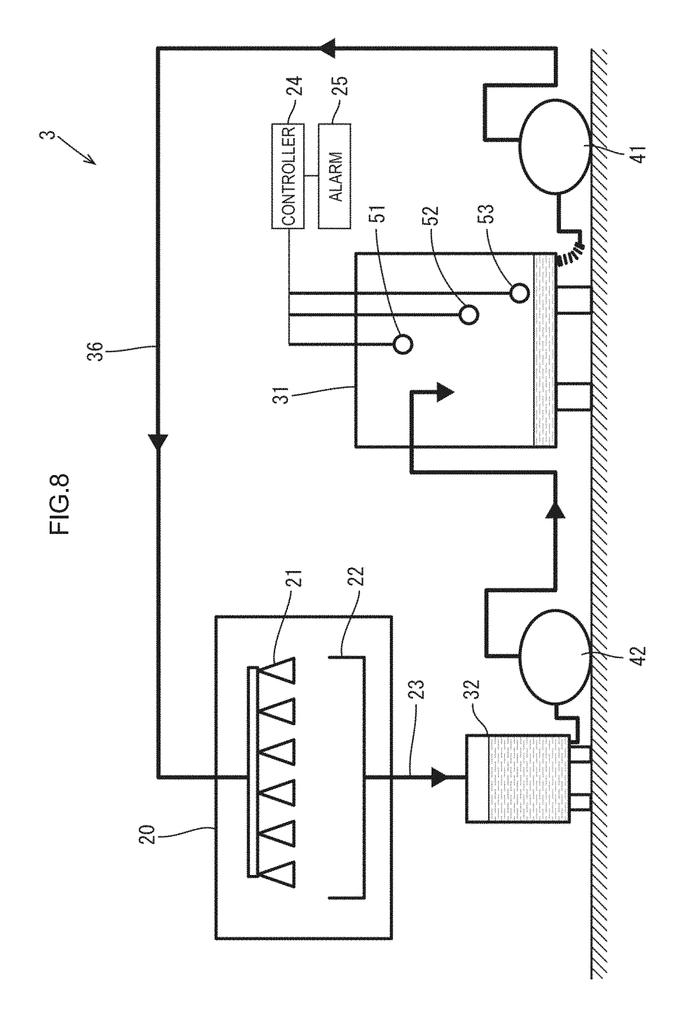

A first embodiment will be described with reference to FIGS. 1 to 8. A liquid circulation system 30 illustrated in FIG. 1 is configured to circulate a chemical solution (a liquid) used in production of a substrate 10 for a liquid crystal panel. As illustrated in FIG. 1, the liquid circulation system 30 includes a main tank 31, an etching device 20 la processing device), a first pump 41, a second pump 42, and a sub tank 32. The main tank 31 stores the chemical solution. The etching device 20 is configured to perform etching on the substrate 10 (a subject) using the chemical solution. The first pump 41 is for feeding the chemical solution from the main tank 31 to the etching device 20. The second pump 42 is for feeding the chemical solution from the etching device 20 to the main tank 31. The etching device 20 includes a shower 21, a processing tank 22, and a discharging pipe 23. The shower 21 includes nozzles through which the chemical solution is sprayed on the substrate 10. The processing tank 22 holds the chemical solution. The chemical solution in the processing tank 22 is discharged through the discharging line 23.

The main tank 31, the first pump 41, the etching device 20, the sub tank 32, and the second pump 42 are connected via pipes 36 and the discharging pipe 23 such that the liquid flows in the above sequence in the circulation. When the first pump 41 is turned on, the chemical solution is fed from the main tank 31 to the shower 21 in the etching device 20. The discharging pipe 23 is connected between the etching device 20 and the sub tank 32. The chemical solution is discharged from the processing tank 22 and held in the sub tank 32. When the second pump 42 is turned on, the chemical solution is fed from the sub tank 32 to the main tank 31. Namely, the sub tank 32 (a buffer tank) stores a portion of the chemical solution flowing from the etching device 20 to the main tank 31. A first liquid level sensor 51, a second liquid level sensor 52, and a third liquid level sensor 53 are installed in the main tank 31 to detect liquid levels in the main tank 31. The liquid level sensors 51, 52, and 53 are connected to a controller 24. The capacity of the sub tank 32 is less than the capacity of the main tank 31. An alarm 25 is connected to the controller 24.

The first liquid level sensor 51 is disposed at the highest position among the liquid level sensors 51 to 53 to detect that the liquid level of the chemical solution reaches the upper limit. The first liquid level sensor 51 is activated when the liquid level is higher than the first liquid level sensor 51 and deactivated when the liquid level is lower than the first liquid level sensor 51. When the liquid level in the main tank 31 reaches the upper limit and the first liquid level sensor 51 is activated, the controller 24 activates the alarm 25 to issue an alert.

The second liquid level sensor 52 is disposed between the first liquid level sensor 51 and the third liquid level sensor 53. The second liquid level sensor 52 is activated when the liquid level in the main tank 31 becomes higher than the second liquid level sensor 52 and deactivated when the liquid level becomes lower than the second liquid level sensor 52. When the second liquid level sensor 52 is deactivated, the controller 24 opens a valve between the second pump 42 and the main tank 31 to feed the chemical solution from the sub tank 32 to the main tank 31. When the second liquid level sensor 52 is activated, the controller 24 closes the valve between the second pump 42 and the main tank 31 to stop the feeding of the chemical solution from the sub tank 32 to the main tank 31. In normal operation as in FIG. 1, the liquid level in the main tank 31 is controlled to correspond with the position of the second liquid level sensor 52 and an amount of the chemical solution in the main tank 31 is maintained at a predefined setting X1.

The third liquid level sensor 53 is disposed at the lowest position amount the liquid level sensors 51 to 53 to detect that the liquid level of the chemical solution reaches the lower limit (a predefined level). The third liquid level sensor 53 is activated when the liquid level of the chemical solution becomes higher than the third liquid level sensor 53 and deactivated when the liquid level of the chemical solution becomes lower than the third liquid level sensor 53. When the third liquid level sensor 53 is deactivated, the controller activates the alarm 25 to issue an alert. An operator of the liquid circulation system may stop the liquid circulation system based on the alarm. Therefore, the liquid level in the main tank 31 is less likely to become lower than the lower limit and thus the first pump 41 is less likely to idle.

The liquid circulation system 30 further includes springs 33 (an adjuster, flexible members) disposed between a bottom 39 of the main tank 31 and a floor surface 11. The springs 33 are coil springs. The springs 33 lift the main tank 31 to adjust a position of the surface of the chemical solution relative to the third liquid level sensor 53 during the replacement of the chemical solution, which will be described in detail later. The springs 33 support the bottom 39 of the main tank 31. The springs 33 are compressed due to the weight of the main tank 31 and the weight of the chemical solution. As the amount of the chemical solution in the main tank 31 decreases, the springs 33 recover and thus the main tank 31 moves up.

The first pump 41 is fixed to the floor surface 11 so that the first pump 41 does not move in the vertical direction and less likely to vibrates while the first pump 41 is in operation. The first pump 41 is connected to the main tank 31 via a flexible hose 34 and thus the first pump 41 does not restrict the vertical movement of the main tank 31. A first end of the flexible hose 34 is connected to the bottom 39 of the main tank 31 and a second end of the flexible hose 34 is connected to the first pump 41.

The liquid level sensors 51 to 53 are not fixed to the main tank 31. The heights at which the first liquid level sensor 51, the second liquid level sensor 52, and the third liquid level sensor 53 are disposed (heights from the floor surface 11) are constant regardless of the vertical movement of the main tank 31. During the normal operation as in FIG. 1, positional relations between the main tank 31 and the liquid level sensors 51 to 53 are fixed using a restriction member 35 (indicated by two-dashed chain lines in FIG. 1) to restrict the vertical movement of the main tank 31.

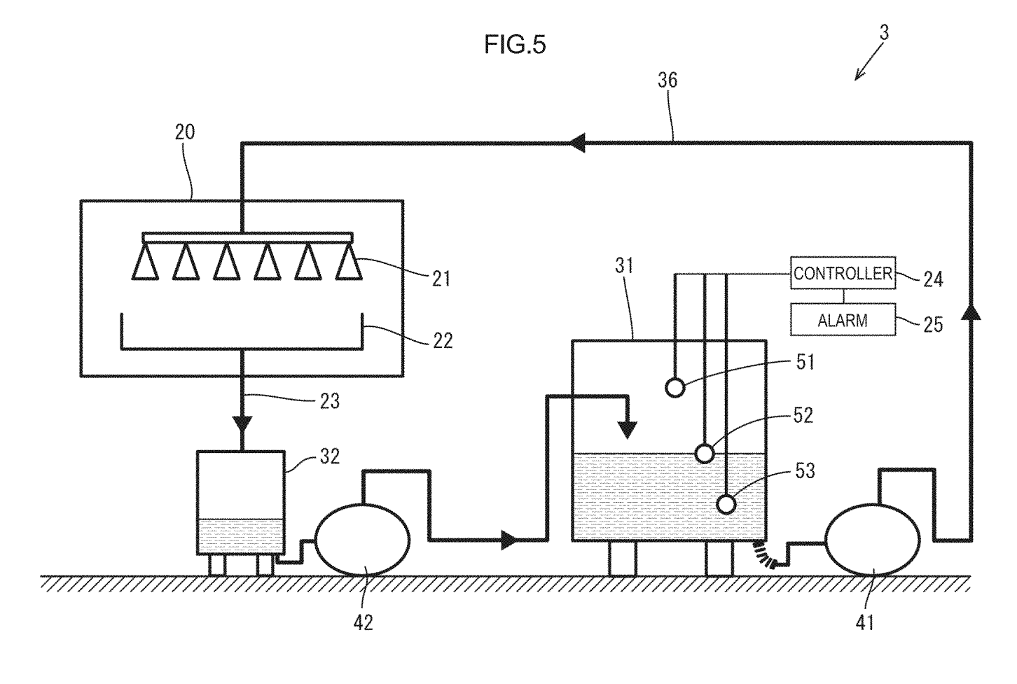

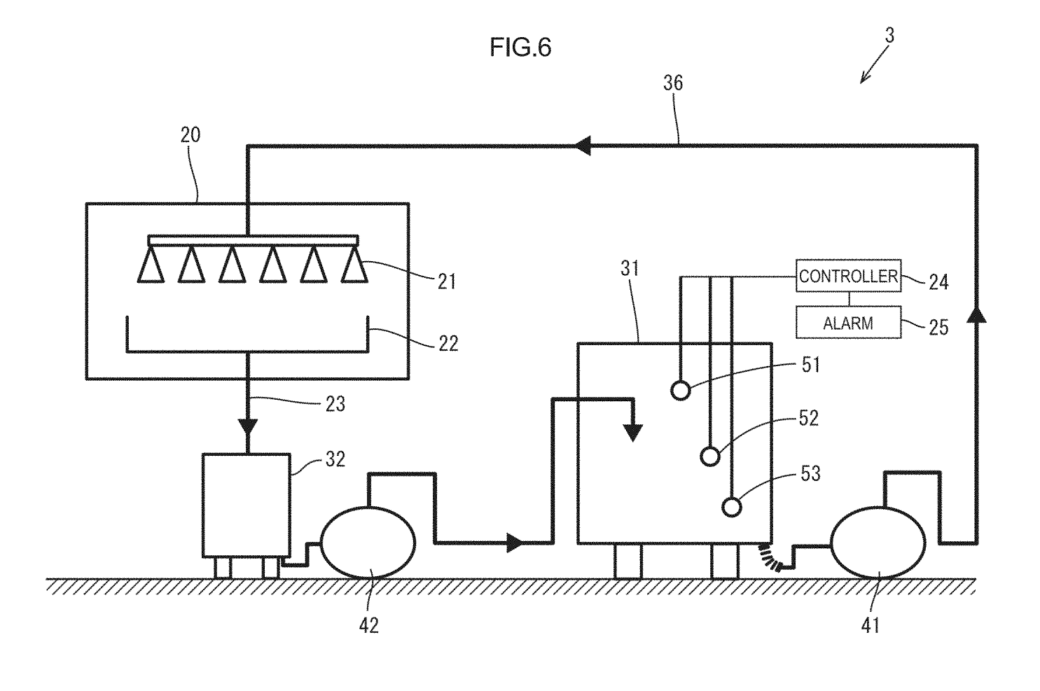

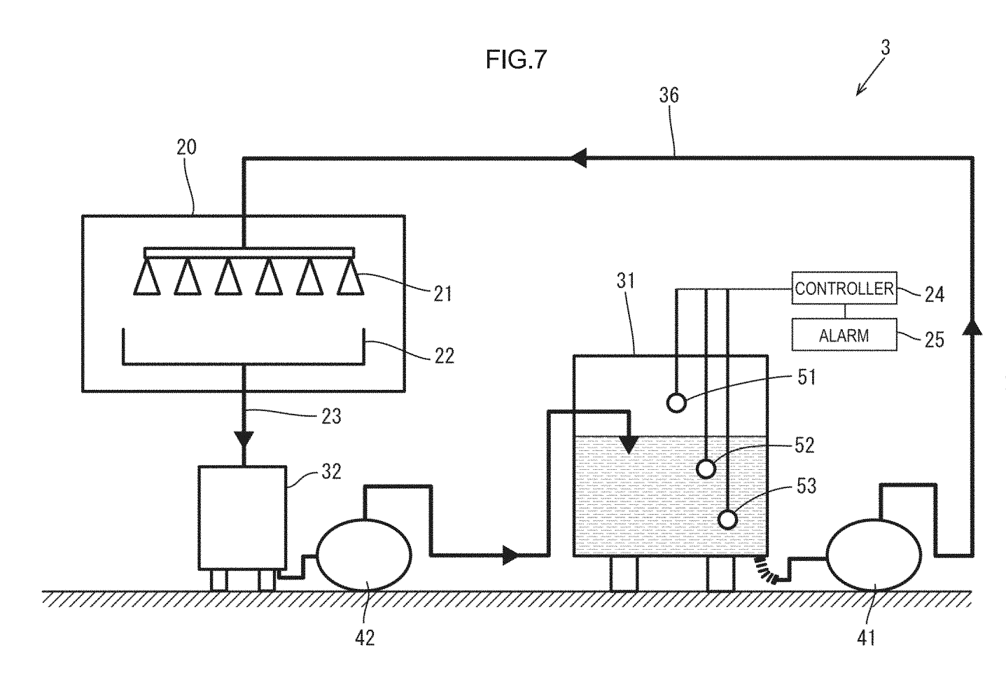

Next, operation and effects will be described. The effects will be described with reference to a comparative example, specifically, a liquid circulation system 3 illustrated in FIGS. 5 to 8. The liquid circulation systems 3 and 30 have the same configuration except for components that support the main tanks 31. The liquid circulation system 3 does not include the springs 33 or the adjuster. In the liquid circulation system 3, the main tank 31 is fixed to the floor surface 11 so that the vertical movement is restricted. During normal operation of the liquid circulation system 3 as in FIG. 5, the liquid level of the chemical solution in the main tank 31 is controlled to correspond with the height of the second liquid level sensor 52. The chemical solution in the main tank 31 has an expiration date and needs to be replaced with a new chemical solution before the expiration date. For the replacement, the chemical solution in the main tank 31, the sub tank 32, and the pipes 36 is discarded as illustrated in FIG. 6. Then, the main tank 31 is refilled with the new chemical solution as illustrated in FIG. 7. The first pump 41 and the second pump 42 are turned on to feed the new chemical solution from the main tank 31 to the etching device 20, to the sub tank 32, and then to the main tank 31 in this sequence to circulate the new chemical solution.

During the circulation, portions of the chemical solution are in the sub tank 32 and the pipes 36. Therefore, the liquid level in the main tank 31 temporarily lowers and the liquid level sensor 53 may turn off. Although the liquid circulation system 3 does not have a malfunction, the controller 24 activates the alarm 25 to issue an alert. To solve such a problem, an extra amount of the chemical solution may be added to the amount of the chemical solution to refill the main tank 31 so that the liquid level in the main tank 31 remains higher than the third liquid level sensor 53 even when the amount of the chemical solution in the main tank 31 is reduced. However, this solution is not preferable from the standpoint of cost-effectiveness and ecological perspective.

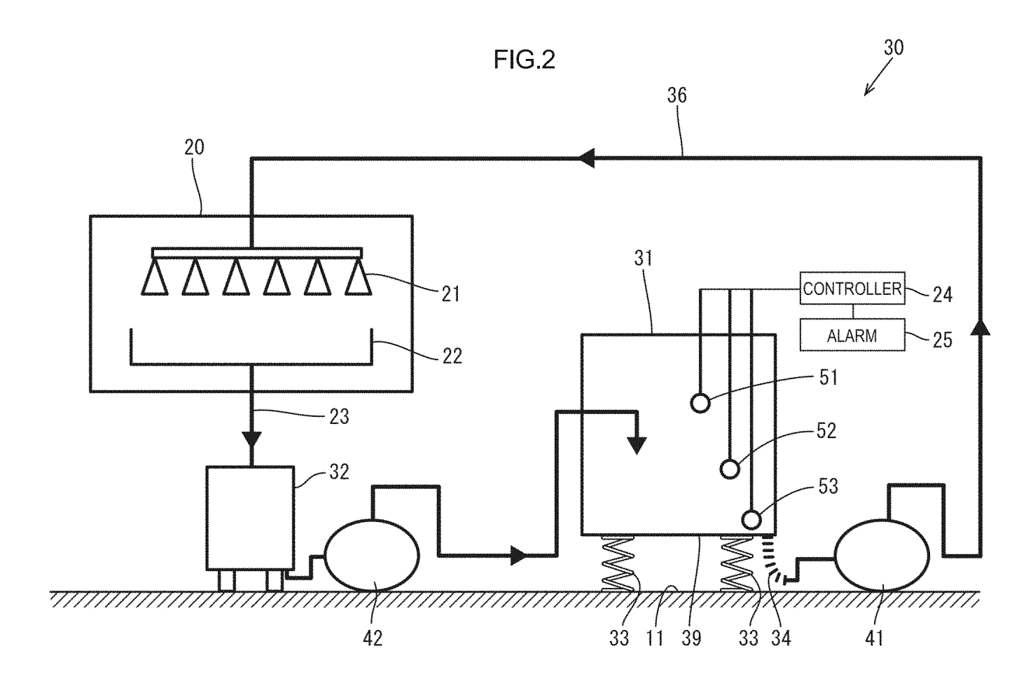

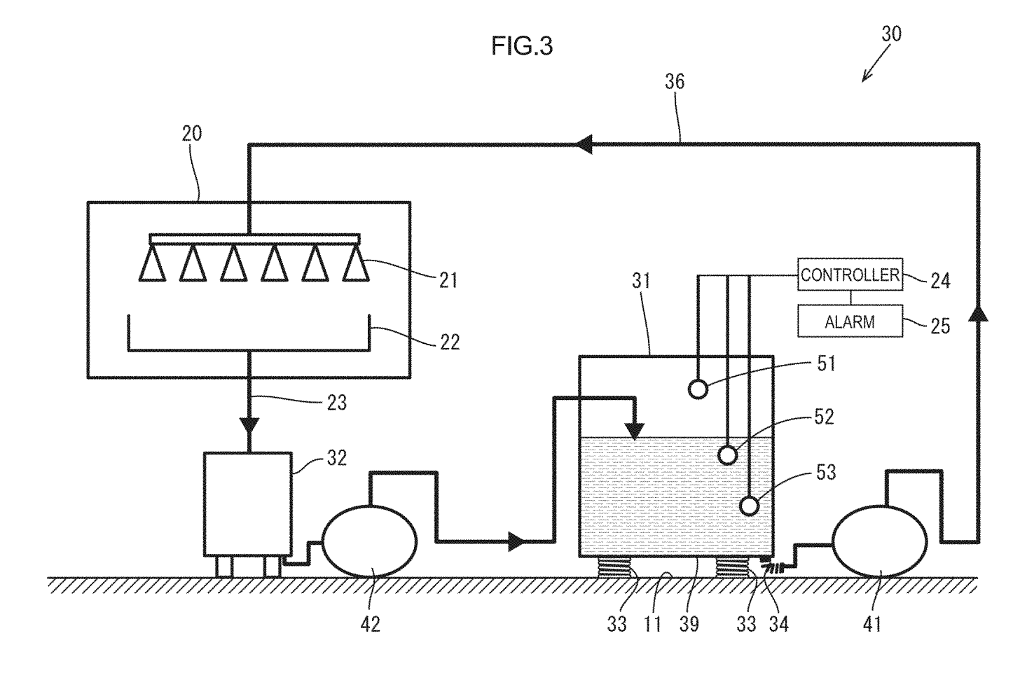

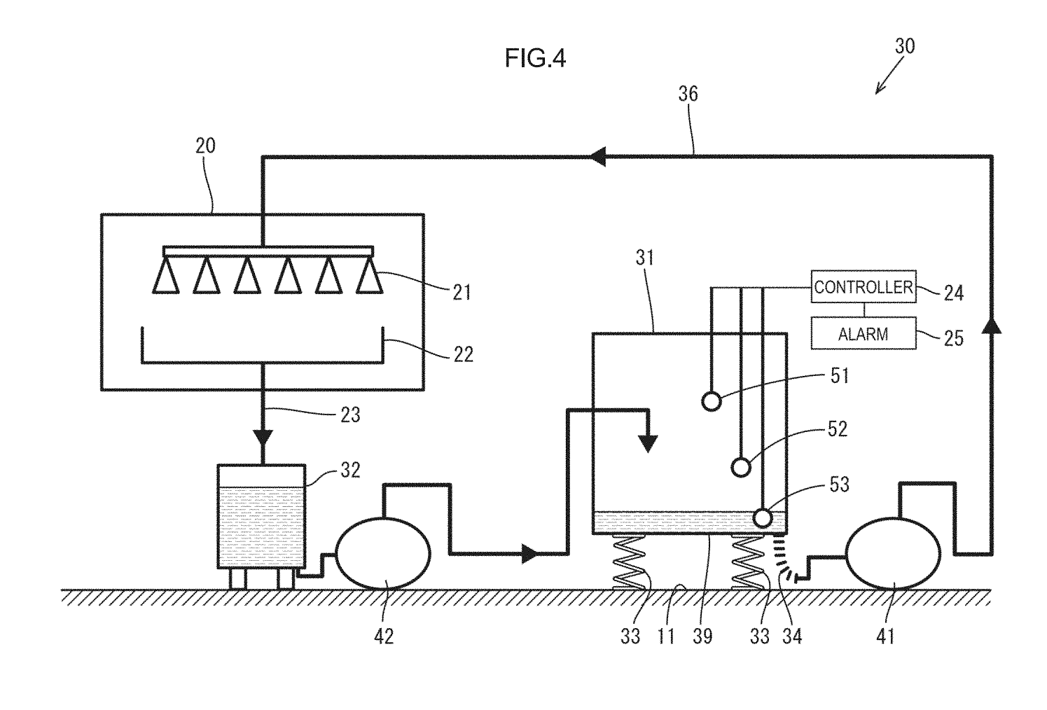

In the liquid circulation system 30, the chemical solution in the main tank 31, the sub tank 32, and the pipes 36 is discarded to replace the chemical solution with a new chemical solution (see FIG. 2). During the replacement, the main tank 31 is emptied and thus the springs 33 recover and the main tank 31 moves up. To replace the chemical solution with the new chemical solution, the restriction member 35 is removed from the main tank 31 and thus the main tank 31 is movable in the vertical direction. As illustrated in FIG. 3, the main tank 31 is refilled with the new chemical solution. The springs 33 are compressed by amounts corresponding to the weight of the new chemical solution and the main tank 31 moves down. Then, the first pump 41 and the second pump 42 are turned on to feed the new chemical solution from the main tank 31, to the etching device 20, to the sub tank 32, and then to the main tank 31 to circulate the new chemical solution.

During the circulation, the amount of the chemical solution in the main tank 31 temporarily decreases as illustrated in FIG. A. As the amount of the chemical solution in the main tank 31 decreases, the springs 33 recover and the main tank 31 moves up. Therefore, the surface of the chemical solution in the main tank 31 is maintained above the liquid level sensor 53 (a threshold). When the chemical solution is fed from the sub tank 32 to the main tank 31 after certain time has elapsed (e.g., after 30 to 60 seconds), the amount of the chemical solution in the main tank 31 increases and the main tank 31 moves down. The chemical solution is fed to the main tank 31 until the amount of the chemical solution in the main tank 31 becomes equal to the predefined setting X1. According to the configuration, the positional relations of the first liquid level sensor 51, the second liquid level sensor 52, and the third liquid level sensor 53 with the main tank 31 in terms of height are returned to the positional relations of those with the main tank 31 in terms of height in the normal operation (see FIG. 1).

The chemical solution in the etching device 20 fed from the main tank 31 using the first pump 41 is fed to the main tank 31 using the second pump 42. The processing using the chemical solution is performed by the etching device 20 while the chemical solution is circulated between the main tank 31 and the etching device 20. As the amount of the chemical solution in the main tank 31 decreases during the replacement of the chemical solution, the main tank 31 moves up. Therefore, the third liquid level sensor 53 is less likely to be activated. An extra amount of the chemical solution is not required to restrict the activation of the third liquid level sensor 53,

The springs 33 are mounted to the main tank 31. The springs 33 are compressed due to the weight of the main tank 31 and the weight of the chemical solution in the main tank 31. As the amount of the chemical solution in the main tank 31 decreases, the springs 33 recover and the main tank 31 moves up. In comparison to a configuration including an actuator to lift the main tank 31 based on an amount of the chemical solution in the main tank 31 detected by a sensor, the configuration of the adjuster including the springs 33 is simpler. With the springs 33, the main tank 31 moves down when the amount of the chemical solution in the main tank 31 increases. Namely, when the main tank 31 moves down due to the increase in amount of the chemical solution in the main tank 31 after the circulation is completed and the chemical solution is returned to the main tank 31, the positional relations between the main tank 31 and the liquid level sensors 51 to 53 with respect to the vertical direction are easily returned to the positional relations thereof with the main tank 31 in terms of height before the main tank 31 is lifted (as in FIG. 1).

With the sub tank 32 that is capable of storing a portion of the chemical solution fed from the etching device 20 to the main tank 31, the feeding of the chemical solution to the main tank 31 is stably performed. When the first pump 41 is first turned on after the replacement of the chemical solution, the new chemical solution is fed from the main tank 31 to the etching device 20, to the sub tank 32, and then to the main tank 31 in this sequence to circulate the new chemical solution. The time required for the circulation of the new chemical solution starting from the main tank 31 and returning to the main tank 31 increases because the portion of the new chemical solution is held in the sub tank 32. Therefore, the liquid level of the new chemical solution in the main tank 31 is more likely to decrease. However, with the springs 33, the surface of the chemical solution in the main tank 31 is less likely to move down. This configuration is especially preferable for the liquid circulation system 30 including the sub tank 32.

### Second Embodiment

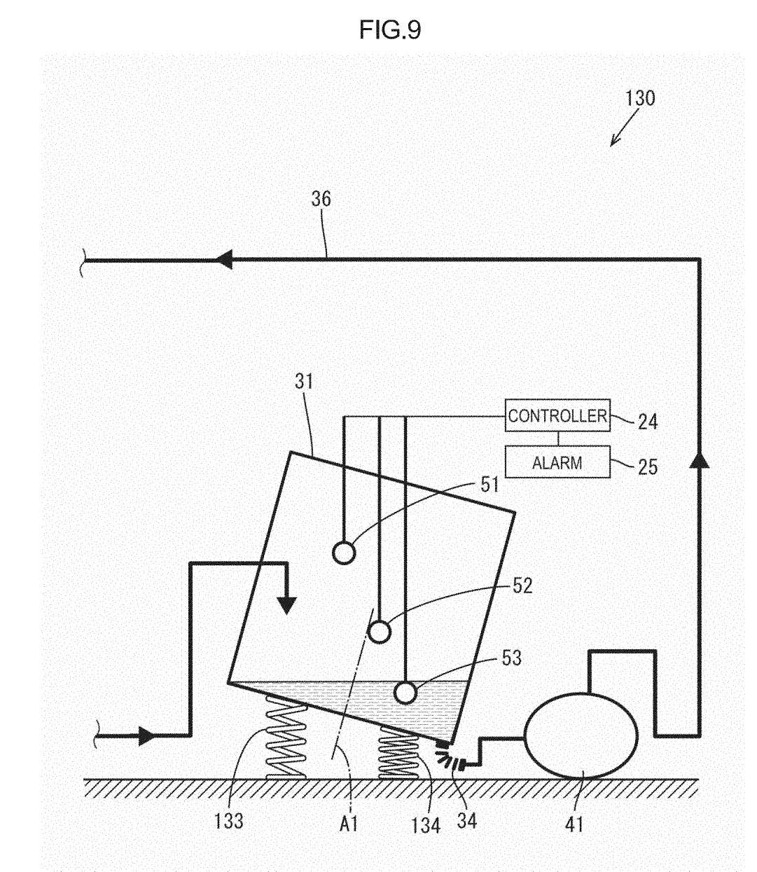

A second embodiment will be described with reference to FIG. 9. A liquid circulation system 130 includes components similar to those in the first embodiment. Those components will be indicated with the same reference signs as those indicating the components in the first embodiment and will not be described in detail. The liquid circulation system 130 includes an adjuster that is different from the adjuster in the first embodiment. The adjuster in this embodiment includes a first spring 133 and a second spring 134. The first spring 133 and the second spring 134 support the main tank 31. The first spring 133 farther from the liquid level sensor 53 has an elastic coefficient greater than an elastic coefficient of the second spring 134 closer to the liquid level sensor 53. The first spring 133 and the second spring 134 are disposed such that a central axis A1 of the main tank 31 is between the first spring 133 and the second spring 134. Because the elastic coefficients are not the same, the first spring 133 and the second spring 134 that are compressed recover differently from each other as the amount of the chemical solution in the main tank 31 decreases. When the main tank 31 moves up as the first spring 133 and the second spring 134 recover, the main tank 31 tils such that the first spring 133 lifts the main tank 31 higher in comparison to the second spring 134. Namely, a portion of the main tank 31 on the second spring 134 side closer to the third liquid level sensor 53 is lower. A depth of the chemical solution on the second spring 134 side is greater than a depth of the chemical solution on the first spring 133 side. According to the configuration, a less amount of the chemical solution is required for maintaining the surface of the chemical solution above the third liquid level sensor 53 in comparison to the first embodiment. In this description, the expression “the main tank 31 moves up” includes a situation in which at least a portion of the main tank 31 moves up as the main tank 31 tilts.

### Other Embodiments

The technology described herein is not limited to the embodiments described above and with reference to the drawings. The following embodiments may be included in the technical scope.

(1) A cleaning device for cleaning the substrate 10 may be an example of the processing device. A cleaning solution may be an example of the liquid. The liquid is not limited to the chemical solution for etching and the cleaning solution. Proper solutions selected for processing performed using the liquid circulation system may be included in the scope of the technology described herein.

(2) Air springs such as air suspensions may be used for the adjuster. The technology described herein may be applied to an adjuster including a sensor for measuring a volume or a weight of the chemical solution in the main tank 31 and an actuator (e.g., a cylinder) for lifting the main tank 31 as the measurement of the chemical solution decreases. To apply this configuration to the second embodiment, two actuators may be required. To tilt the main tank 31, different amounts of lift are set for the actuators, respectively.

(3) The main tank 31 may be hung with springs.

(4) The sub tank 32 may be omitted.

(5) The technology described herein may be applied to an adjuster including a sensor for measuring a volume or a weight of the chemical solution in the main tank 31 and an actuator for lowering the third liquid level sensor 53 form a predefined position as the measurement of the chemical solution decreases. According to the configuration, the surface of the chemical solution in the main tank 31 is maintained above the third liquid level sensor 53. The third liquid level sensor 53 is returned to the predefined position after the replacement of the chemical solution is completed.

1. A liquid circulation system comprising:
a tank for storing a liquid;
a processing device for processing a subject using the liquid;
a first pump for feeding the liquid in the tank to the processing device;
a second pump for feeding the liquid used in the processing device to the tank;
a liquid level sensor for detecting a liquid level of the liquid in the tank below a threshold; and
an adjuster for lifting the tank and adjusting a position of a surface of the liquid relative to the liquid level sensor to maintain the surface of the liquid above the liquid level sensor when an amount of the liquid in the tank is reduced.

2. The liquid circulation system according to claim 1, wherein
the adjuster includes at least one elastic member mounted to the tank and compressed by the tank storing the liquid, and
the at least one elastic member recover as the amount of the liquid in the Lank decreases to lift the tank.

3. The liquid circulation system according to claim 2, wherein
the at least one elastic member includes two elastic members to support a bottom of the tank, and
the elastic members have elastic coefficients different from each other.

4. The liquid circulation system according to claim 1, further comprising a sub tank connected between the processing device and the tank for storing a portion of the liquid.

5. A liquid circulation system comprising:
a tank for storing a liquid;
a processing device for processing a subject using the liquid;
a first pump for feeding the liquid in the tank to the processing device;
a second pump for feeding the liquid used in the processing device to the tank;
a liquid level sensor for detecting a liquid level of the liquid in the tank below a threshold; and
an adjuster for lowering the liquid level sensor and adjusting a position of a surface of the liquid level sensor relative to a surface of the liquid to maintain the surface of the liquid above the liquid level sensor when an amount of the liquid in the tank is reduced.

6. The liquid circulation system according to claim 5, further comprising a sub tank connected between the processing device and the tank for storing a portion of the liquid.
